(19) United States
(12) Patent Application Publication
(10) Pub. No.: US 2026/0185219 A1
(43) Pub. Date: Jul. 2, 2026

(54) SUBSTRATE PROCESSING APPARATUS

(71) Applicant: TES CO., LTD, Yongin-si (KR)

(72) Inventors: Kyung-Ho JANG, Yongin-si (KR); Min-Wook KANG, Yongin-si (KR); Byeong-Ho YUN, Yongin-si (KR)

(73) Assignee: TES CO., LTD, Yongin-si (KR)

(21) Appl. No.: 19/409,593

(22) Filed: Dec. 4, 2025

(30) Foreign Application Priority Data
Dec. 26, 2024 (KR) 10-2024-0197785

(51) Int. Cl. C23C 16/44; C23C 16/455

(52) U.S. Cl. CPC C23C 16/4408; C23C 16/45565

(57) ABSTRACT

A substrate processing apparatus includes a chamber, an upper showerhead plate, a stem, and a backplate. The chamber provides a processing space in which a process for a substrate is performed. The upper showerhead plate is provided in an upper region of an interior of the chamber to supply purge gas. The stem is connected to an upper surface of the upper showerhead plate to be internally supplied with the purge gas, and is formed with a first supply hole. The backplate forms a purge gas space between the backplate and the upper surface of the upper showerhead plate, and is formed with a second supply hole.

### CROSS-REFERENCE TO RELATED APPLICATIONS

A claim for priority under 35 U.S.C. § 119 is made to Korean Patent Application No. 10-2024-0197785 filed on Dec. 26, 2024, in the Korean Intellectual Property Office, the entire contents of which are hereby incorporated by reference.

### BACKGROUND OF THE INVENTION

### Field of the Invention

The present invention relates to a substrate processing apparatus, and more particularly to the substrate processing apparatus capable of effectively exhausting residual gases remaining inside a chamber to prevent particle generation that may be caused by the residual gases.

### Description of the Related Art

A substrate processing apparatus according to the prior art deposits a thin film of a predetermined thickness on one side of a substrate, for example, on an upper surface of the substrate. In this case, if the thin films are deposited superimposed on the upper surface of the substrate, stress of the thin films can cause the substrate to bow.

If the substrate is bowed as such, it becomes difficult to locate the substrate in a correct position when the substrate is processed in various substrate processes that follow, and this bowing phenomenon reduces precision of the processes, especially while the precision of the substrate processing process is increasing each day. Therefore, to prevent the bowing phenomenon of the substrate described above, a thin film of a predetermined thickness is deposited on a lower surface of the substrate.

Such a substrate processing apparatus is provided with an upper showerhead for supplying purge gas and the like to an upper portion of the substrate, and a lower showerhead for supplying process gas to a lower portion of the substrate.

However, even if the purge gas is supplied through the upper showerhead, the process gas supplied from the lower showerhead diffuses into an interior of the chamber and remains in a space located above the upper showerhead to generate various byproducts. In particular, residual gas is not exhausted and remains in an inside of a door opening through which the substrate is taken in and out of the chamber, thereby generating various byproducts and causing particles.

In addition, in the substrate processing apparatus according to the prior art, when the upper showerhead is replaced or repaired, a large amount of time and manpower is required due to a weight of the upper showerhead.

### SUMMARY OF THE INVENTION

The present invention is contemplated to solve problems in the prior art mentioned above. Thus, it is an object of the present invention to provide a substrate processing apparatus capable of effectively exhausting residual gases remaining in a processing space above an upper showerhead, a door opening of a chamber and the like by simultaneously performing internal purge of an upper showerhead and external purge of the upper showerhead.

Further, it is an object of the present invention to provide a substrate processing apparatus having a purge gas supply system of double flow paths without being affected by an external environment during a process for a substrate.

Further, it is an object of the present invention to provide a substrate processing apparatus capable of improving working environment by reducing a weight burden of an upper showerhead when the upper showerhead is replaced or repaired.

Further, it is an object of the present invention to provide a substrate processing apparatus capable of forming symmetrical flow paths of purge gas from an edge of an upper showerhead toward a bottom, and further capable of guiding residual gas and byproduct to an exhaust outlet by orienting the purge gas toward the bottom.

To achieve the above object, the present invention may provide a substrate processing apparatus comprising: a chamber configured to provide a processing space in which a process for a substrate is performed; an upper showerhead plate provided in an upper region of an interior of the chamber and configured to supply purge gas; a stem connected to an upper surface of the upper showerhead plate and configured to be internally supplied with the purge gas, the stem being formed with a first supply hole; and a backplate configured to form a purge gas space between the backplate and the upper surface of the upper showerhead plate and formed with a second supply hole.

The backplate may be spaced apart from the stem on the upper surface of the upper showerhead plate.

A gap between the stem and the backplate may be from about 0.5 mm to about 5 mm on the upper surface of the upper showerhead plate.

The purge gas supplied from the first supply hole may flow into the purge gas space through the second supply hole.

The first supply hole and the second supply hole may be formed at substantially the same height from the upper surface of the upper showerhead plate.

The backplate may include: a body spaced apart from the upper surface of the upper showerhead plate and formed with an opening through which the stem passes; and a first extension extending downwardly from an inner edge of the body and connected to the upper surface of the upper showerhead plate.

The backplate may further include a second extension extending downwardly from an outer edge of the body and connected to the upper surface of the upper showerhead plate.

In this case, the second supply hole may be provided in the first extension.

Meanwhile, the upper showerhead plate and the backplate may be made of aluminum material or ceramic material.

Details of examples or implementations will be described in the following with reference to the accompanying drawings. Other features will be apparent from the description and drawings, and from the claims.

### BRIEF DESCRIPTION OF THE DRAWINGS

The present invention will become more fully understood from the detailed description given below and the accompanying drawings, which are given by illustration only, and thus are not intended to limit the scope of the present Invention, wherein:

FIG. 1 is a side sectional view of a substrate processing apparatus according to one embodiment of the present invention;

FIG. 2 is an enlarged side sectional view of an upper showerhead in FIG. 1;

FIG. 3 is an upper perspective view of a backplate; and

FIG. 4 is a side sectional view of a substrate processing apparatus according to another embodiment of the present invention.

### DETAILED DESCRIPTION OF THE PREFERRED EMBODIMENT

Description for the present invention will now be given in detail according to examples disclosed herein, with reference to the accompanying drawings.

For the sake of a brief description with reference to the drawings, the same or equivalent components may be provided with the same reference numbers, and description thereof will not be repeated. In the following, any conventional art which is well-known to one of ordinary skill in the relevant art has generally been omitted for the sake of brevity. The accompanying drawings are used to help easily understand various technical features and it should be understood that the examples presented herein are not limited by the accompanying drawings. As such, the present invention should be construed to extend to any alterations, equivalents, and substitutes in addition to those which are particularly set out in the accompanying drawings.

A singular representation may include a plural representation unless it represents a definitely different meaning from the context.

It will be understood that although the terms “first,” “second,” etc., may be used herein to describe various components, these components should not be limited by these terms. These terms are only used to distinguish one component from another component.

It should be understood that when a component is referred to as being “connected to” or “coupled to” another component, this component may be directly connected to or coupled to another component, or any intervening components may be present between the components. In contrast, when a component is referred to as being “directly connected to” or “directly coupled to” another component, there are no intervening components present.

Terms such as “comprise”, “include” or “have” are used herein and should be understood that they are intended to indicate an existence of several components, functions or steps, disclosed in the specification, and it is also understood that greater or fewer components, functions, or steps may likewise be utilized. Moreover, due to the same reasons, it is also understood that the present invention includes any combinations of features, numerals, steps, operations, components, parts and the like partially omitted from the related or involved features, numerals, steps, operations, components, and parts described using the aforementioned terms unless deviating from the intentions of the original disclosure.

Hereinafter, a configuration of a substrate processing apparatus 1000 according to an embodiment of the present invention will be specifically described with reference to drawings.

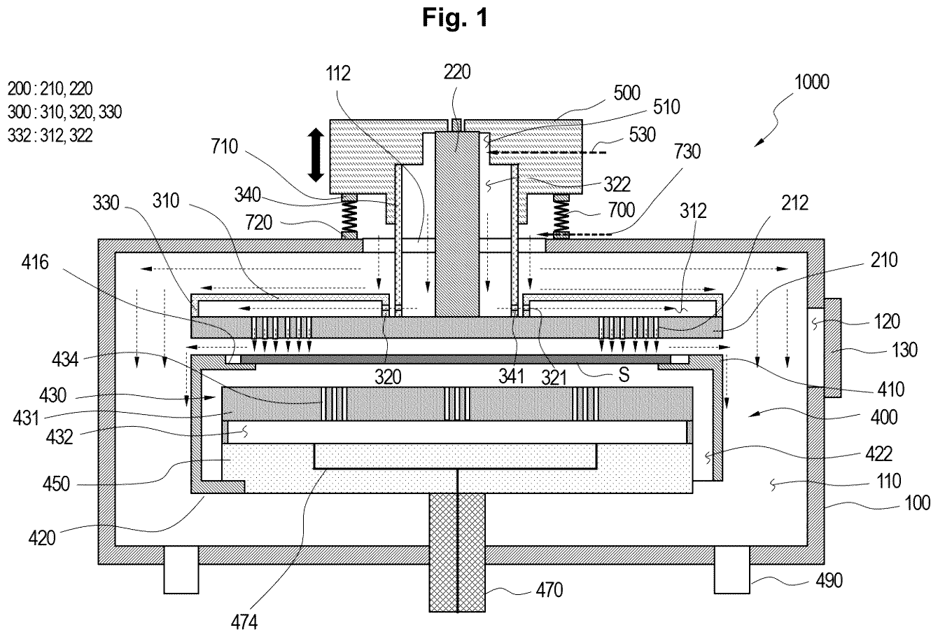

FIG. 1 is a side sectional view of the substrate processing apparatus 1000 according to one embodiment of the present invention.

Referring to FIG. 1, the substrate processing apparatus 1000 may comprise a chamber 100 providing a processing space 110 in which a process for a substrate S is performed, an upper showerhead plate 210 provided in an upper region of an interior of the chamber 100 to supply purge gas, a stem 340 connected to an upper surface of the upper showerhead plate 210 to be internally supplied with the purge gas and formed with a first supply hole 341, and a backplate 300 forming a purge gas space 312 between the backplate 300 and the upper surface of the upper showerhead plate 210, and formed with a second supply hole 321. Hereinafter, an upper surface of any components also indicates a top surface thereof, and likewise, a lower surface of any components also indicates a bottom surface thereof.

First, the chamber 100 may provide, in an interior thereof, the processing space 110 in which various components required for a deposition process on the substrate S are accommodated.

At one side of the chamber 100, a door opening 120 through which the substrate S is loaded into the processing space 110 or unloaded from the processing space 110, may be provided, and a door 130 may be provided to the door opening 120.

Meanwhile, a lower region of the processing space 110 of the chamber 100 may be provided with a substrate supporting unit 400 that supports the substrate S and exposes a lower surface of the substrate S to process gas.

The substrate supporting unit 400 supports a periphery of the lower surface of the substrate S at the lower region of the processing space 110. A lower showerhead 430 may be provided in an interior of the substrate supporting unit 400, and the process gas may be supplied to the lower surface of the substrate S by the lower showerhead 430. The substrate supporting unit 400 may be connected with a connecting bar 470 extending downwardly.

Meanwhile, the substrate supporting unit 400 may include a substrate holder 410 supporting the periphery of the lower surface of the substrate S, and the lower showerhead 430 described above may be provided in an interior of the substrate holder 410.

The lower showerhead 430 may include a lower showerhead plate 431 and a lower plate 450 in which a heat exchange channel (not shown) is formed.

In this case, the substrate holder 410 may be supported at a lower end portion thereof by a fixing member (or fixture) 420 connected to the lower plate 450.

The substrate holder 410 may extend upwardly from the fixing member 420, and an upper end portion of the substrate holder 410 may be bent inwardly.

In this case, a recess 416 may be formed in the upper end portion of the substrate holder 410. Accordingly, when the substrate S is seated on the substrate holder 410, the substrate S may be inserted into the recess 416 to have the lower surface of the periphery of the substrate S supported.

Meanwhile, the process gas may be supplied to the lower showerhead 430 via a lower supply line 474 which passes through the connecting bar 470.

The lower showerhead 430 may be provided with a buffer space 432, and the buffer space 432 may be provided between the lower showerhead plate 431 and the lower plate 450. Although not shown in the accompanying drawings, a baffle or a blocking plate for dispersion of gas may be inserted between the lower showerhead plate 431 and the lower plate 450 or inserted in the buffer space 432.

Meanwhile, the heat exchange channel (not shown) may be formed in the lower plate 450, so that a heat exchange fluid and the like may flow along the heat exchange channel to adjust a temperature of the process gas or a temperature inside the chamber 100 through heat exchange.

Further, the lower plate 450 may serve to support the lower showerhead plate 431 and the substrate holder 410. In this case, the lower showerhead plate 431 may be connected to an upper surface of the lower plate 450. Additionally, the fixing member 420, which supports the lower end portion of the substrate holder 410, may be connected to the lower plate 450.

In this case, a plurality of fixing members (or fixtures) 420 may be provided to the substrate supporting unit 400 and may be spaced apart by a predetermined interval along an outer circumference of the lower plate 450. That is, when the plurality of fixing members 420 are provided, spaces between neighboring fixing members 420 may be open downward to communicate with the interior of the chamber 100. Thus, a space between side surfaces of the lower showerhead plate 431 and the lower plate 450 and the inner opposite surface of the substrate holder 410 may form an exhaust channel 422.

In this case, a portion of the process gas supplied from the lower showerhead 430 may be discharged through the exhaust channel 422 to the lower region of the interior of the chamber 100, and may be exhausted to an exterior of the chamber 100 through an exhaust outlet 490 provided at a lower portion of the chamber 100.

Meanwhile, an upper portion of the chamber 100, particularly an upper region of the interior of the chamber 100 may be provided with the upper showerhead 200 for supplying the purge gas, such as an inert gas, toward the upper surface of the substrate S. The upper showerhead 200 may be made of, for example, Aluminum Nitride (AlN) or the like.

The upper showerhead 200 may include an upper showerhead plate 210 provided in the upper region of the interior of the chamber 100 and arranged to face the substrate supporting unit 400 or the substrate S to supply the purge gas, and a showerhead connector 220 extending upwardly from a center portion of the upper showerhead plate 210.

The upper showerhead plate 210 may have an area or a diameter that is approximately greater than that of the substrate S. Further, the upper showerhead plate 210 may have the diameter or area approximately corresponding to that of the substrate supporting unit 400.

A plurality of through holes 212 may be formed in the upper showerhead plate 210. Through the through holes 212, the purge gas may be supplied towards the substrate S below.

In addition, the upper showerhead plate 210 may be made of metal, such as aluminum, or ceramic material (e.g., AlN).

However, in order to solve a problem that a thin film for stress compensation deposited on the lower surface of the substrate S to compensate for bowing of the substrate S has weak heat resistance and is delaminated in a subsequent high-temperature process, it is necessary to deposit the thin film for stress compensation in a high-temperature environment of 500° C. or higher to secure heat resistance. In this regard, it is desirable that the upper showerhead plate 210 is made of the ceramic material so as to have low thermal deformation and high durability against heat.

Here, when the upper showerhead plate 210 is made of the ceramic material, a plasma electrode and a heater electrode may be embedded therein.

Meanwhile, the showerhead connector 220 may extend upwardly from an approximate center of the upper showerhead plate 210. An upper end portion of the showerhead connector 220 may protrude from the upper portion of the chamber 100 through an upper opening 112 of the chamber 100.

The upper end portion of the showerhead connector 220 may be connected to an upper showerhead fixture 500 at an outside of the chamber 100.

The upper showerhead fixture 500 may be disposed on an outer side of the upper portion of the chamber 100, and may be connected to the showerhead connector 220. In this case, the upper showerhead fixture 500 may be vertically movable.

For example, a plurality of support bars (not shown) may be provided adjacent to the chamber 100, and the upper showerhead fixture 500 may elevate and descend along the support bars. The configuration for raising and lowering the upper showerhead fixture 500 is described by way of example and may be implemented in various mechanisms.

When the upper showerhead fixture 500 is raised and lowered in a vertical direction, the showerhead connector 220 and the upper showerhead plate 210 may also be raised and lowered together with the upper showerhead fixture 500. That is, the upper showerhead 200 may be configured to be raised and lowered.

Meanwhile, the upper showerhead fixture 500 may further include a bellows 700, which connects the upper showerhead fixture 500 and the chamber 100 to each other and which expands and contracts, in order to maintain an internal pressure in the chamber 100 when the upper showerhead fixture 500 is raised and lowered.

The bellows 700 may be disposed between an upper connector 710 and a lower connector 720. The upper connector 710 may be disposed on the upper showerhead fixture 500 and the lower connector 720 may be disposed on an upper surface of the chamber 100.

Additionally, a connection groove 510 may be formed on an inner side (or inner portion) of the upper showerhead fixture 500, and the upper end portion of the showerhead connector 220 may be inserted into the connection groove 510 for connection to the fixture 500.

Meanwhile, the substrate processing apparatus 1000 may include the stem 340 connected to the upper surface of the upper showerhead plate 210 to be internally supplied with the purge gas, and having the first supply hole 341 formed therein, and the backplate 300 forming the purge gas space 312 between the backplate 300 and the upper surface of the upper showerhead plate 210, and having the second supply hole 321 formed therein.

For example, the stem 340 may be provided in the form of a column with an open top and bottom. In this case, an upper end portion of the stem 340 may be connected to the upper showerhead fixture 500, and a lower end portion of the stem 340 may be connected to the upper surface of the upper showerhead plate 210.

Accordingly, the stem 340 may be spaced apart from the showerhead connector 220 by a predetermined distance and may extend downwardly in the upper showerhead fixture 500. That is, the stem 340 may provide a stem space 322 in which the purge gas flows between the stem 340 and the showerhead connector 220.

Further, the first supply hole 341 may be formed in the stem 340. The first supply hole 341 may serve to supply the purge gas of the stem space 322 to an outside thereof. For example, the purge gas supplied from the first supply hole 341 may be supplied to the purge gas space 312 of the backplate 300.

The first supply hole 341 may be formed adjacent to the lower end portion of the stem 340. Further, the first supply hole 341 may be provided in the form of a slit (not shown).

Meanwhile, the backplate 300 may be provided on the upper surface of the upper showerhead plate 210. The backplate 300 and the upper surface of the upper showerhead plate 210 may form the purge gas space 312 therebetween, such that the purge gas supplied from the first supply hole 341 may flow into the purge gas space 312.

That is, the purge gas introduced into the purge gas space 312 may be supplied through the upper showerhead plate 210 towards the substrate S below.

In one example, the backplate 300 may be made of the aluminum or ceramic material. In particular, the backplate 300 may be implemented in the ceramic material to provide heat resistance in response to high temperature processes and chemical resistance in response to chamber cleaning gases.

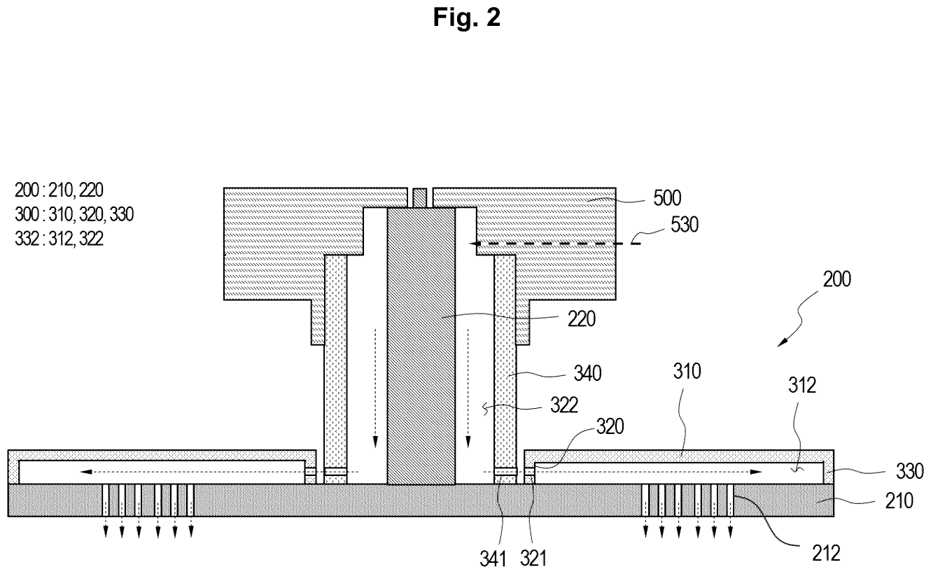

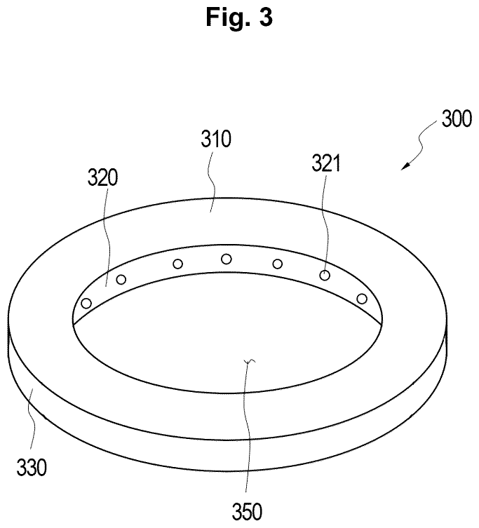

FIG. 2 is an enlarged side sectional view of the upper showerhead 200, and FIG. 3 is an upper perspective view of the backplate 300.

Referring to FIGS. 1 to 3, the backplate 300 may include a body 310 spaced apart from the upper surface of the upper showerhead plate 210 and formed with an opening 350 through which the stem 340 penetrates, and a first extension 320 extending downwardly from an inner edge of the body 310 and connected to the upper surface of the upper showerhead plate 210.

The backplate 300 may further include a second extension 330 extending downwardly from an outer edge of the body 310 and connected to the upper surface of the upper showerhead plate 210.

The body 310 may have a roughly “donut” shape, and may have the opening 350 formed in its center portion. The opening 350 may be arranged to allow the stem 340 and the showerhead connector 220 to pass therethrough.

Further, the first extension 320 formed on the inner edge of the body 310 and the second extension 330 formed on the outer edge of the body 310 may be connected to the upper showerhead plate 210.

Thus, a space enclosed by the body 310, the first extension 320, the second extension 330 and the upper surface of the upper showerhead plate 210 may form the purge gas space 312.

In this case, the second supply hole 321 may be provided in the first extension 320. Although not shown in the drawings, the second supply hole 321 may also be provided in the form of a slit.

The first supply hole 341 and the second supply hole 321 may be formed at substantially the same height from the upper surface of the upper showerhead plate 210. Moreover, the first supply hole 341 and the second supply hole 321 may be arranged in concentric circles. That is, the first supply hole 341 and the second supply hole 321 may be arranged concentrically with each other.

Therefore, the purge gas supplied to the outside of the stem 340 from the first supply hole 341 may enter or flow into the purge gas space 312 through the second supply hole 321.

In this case, a space or an area between the first supply hole 341 and the second supply hole 321 may be exposed to the processing space 110. That is, a flow path may not be formed by any separate member between the first supply hole 341 and the second supply hole 321, but may be configured in a form exposed to the processing space 110. However, as the first supply hole 341 and the second supply hole 321 may be configured to be sufficiently adjacent by a predetermined distance, they may naturally form a flow path.

Thus, the stem space 322 and the purge gas space 312 may be connected to (or communicate with) each other to form a flow space 332 in which the purge gas flows. The purge gas traveling downwardly through the flow space 332 may be supplied through the through hole 212 of the upper showerhead plate 210 toward the substrate S below.

Meanwhile, the backplate 300 may be spaced apart from the stem 340 by a predetermined distance on the upper surface of the upper showerhead plate 210. However, if the spacing or gap between the backplate 300 and the stem 340 is excessively great, it may be difficult for the purge gas ejected from the first supply hole 341 to flow into the second supply hole 321. Accordingly, the gap between the backplate 300 and the stem 340 may be adjusted to facilitate the flow of the purge gas into the second supply hole 321.

For example, the gap between the stem 340 and the backplate 300, or between the stem 340 and the first extension 320, may be from about 0.5 mm to about 5 mm.

If the gap between the stem 340 and the first extension 320 is less than 0.5 mm, a problem may occur in which the stem 340 and the first extension 320 come into contact with each other and break, due to a difference in horizontal thermal expansion rates between the stem 340 and the first extension 320. In addition, when the gap between the stem 340 and the first extension 320 is less than 0.5 mm, if the first supply hole 341 and the second supply hole 321 are not exactly aligned one-to-one, a problem that the flow and dispersion of the purge gas is rather impeded, may occur.

In contrast, when the gap exceeds 5 mm, a problem may arise that a large amount of purge gas leaks to the outside of the backplate 300 through the gap between the stem 340 and the first extension 320, resulting in a reduction of the purge gas pressure supplied to the substrate S.

Meanwhile, the present invention may establish a purge gas supply system with double or dual flow paths that can simultaneously perform inner purge of the upper showerhead 200 and outer purge of the upper showerhead 200, and further, can perform such inner and outer purges so as not to be affected by external environment during the process. Hereinafter, the purge gas supply system will be described in detail.

Referring to FIG. 1, in the present invention, the purge gas may be supplied in two ways along an outer side (or outer surface) of the backplate 300 and along a space between the backplate 300 and the upper showerhead 200.

The purge gas supplied to the outer side of the backplate 300 may purge various residual gases and byproducts remaining in the processing space 110 above the backplate 300.

Further, the purge gas supplied along the space between the backplate 300 and the upper showerhead 200 may be supplied to the substrate S via the upper showerhead plate 210.

Here, to distinguish between the purge gas supplied along the space between the backplate 300 and the upper showerhead 200 and the purge gas supplied to the outer side of the backplate 300, they are designated as first purge gas and second purge gas, respectively. The first purge gas and second purge gas are composed of the same kind of gas, but are not limited thereto and may be composed of different kinds of gas.

Accordingly, the outer purge on the outer side of the backplate 300 and the inner purge of the upper showerhead 200 may prevent the process gas supplied to the lower surface of the substrate S from entering (or flowing to) the upper surface of the substrate S.

For example, a first purge gas supply line 530 may be connected to the upper showerhead fixture 500, such that purge gas may be supplied to the stem space 322 between the stem 340 and the showerhead connector 220.

The first purge gas supplied to the stem space 322 may travel downwardly and enter the purge gas space 312 between the backplate 300 and the upper showerhead plate 210 via the first supply hole 341 of the stem 340 and the second supply hole 321 of backplate 300. From the purge gas space 312, the first purge gas may be supplied through the through hole 212 of the upper showerhead plate 210 towards the substrate S below.

Meanwhile, the substrate processing apparatus 1000 may further include a second purge gas supply line 730 for supplying the purge gas to an outer side of the backplate 300.

The second purge gas supply line 730 may supply the second purge gas to the outer side of the backplate 300 via the bellows 700. For example, the second purge gas supply line 730 may pass through the upper connector 710 or the lower connector 720 to supply the second purge gas to the outer side of the backplate 300.

The second purge gas may be supplied to the interior of the chamber 100 through the upper opening 112 of the chamber 100, and may be supplied along the outer side of the backplate 300 to the processing space 110 above the backplate 300. Thus, the second purge gas may purge various residual gases, byproducts or the like remaining in the processing space 110 above the backplate 300 to the lower region of the chamber 100 for exhaust.

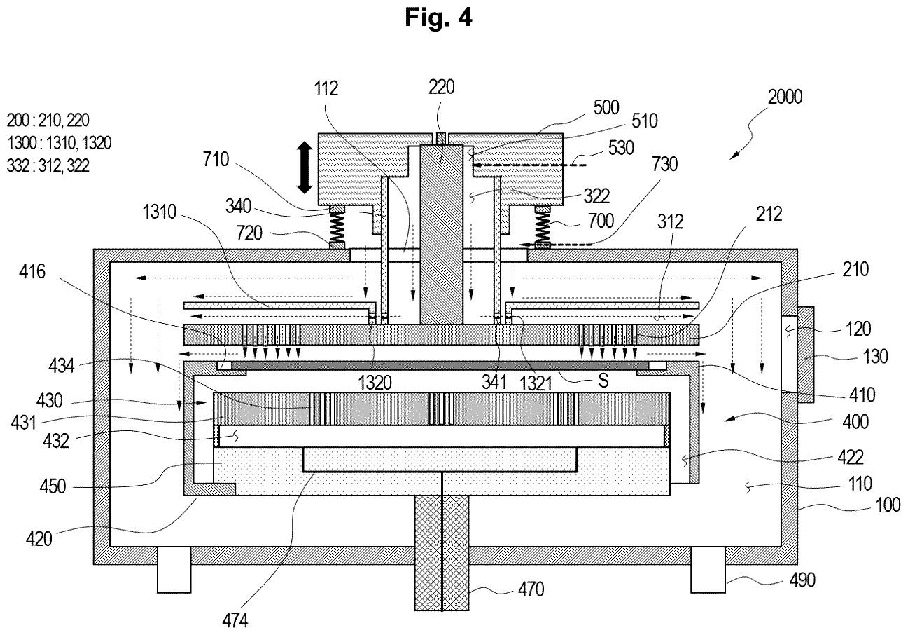

Meanwhile, FIG. 4 is a side sectional view illustrating a substrate processing apparatus 2000 according to another embodiment. In FIG. 4, the same reference numerals are used for the same components as in the previously described embodiment.

Referring to FIG. 4, in this embodiment, the backplate 1300 may include a body 1310 and a first extension 1320 extending downwardly from an inner edge of the body 1310. The first extension 1320 may be connected to the upper surface of the upper showerhead plate 210.

That is, in this embodiment, the purge gas space 312 between the backplate 1300 and the upper showerhead plate 210 may not be closed or sealed and may have an open configuration at an outer edge of the backplate 1300.

Thus, a portion of the first purge gas introduced into the purge gas space 312 from the stem space 322 at the interior of the stem 340 via the first supply hole 341 and a second supply hole 1321 may be supplied to the substrate S below through the through hole 212 of the upper showerhead plate 210.

Further, a portion of the first purge gas introduced into the purge gas space 312 may flow outward through an open portion at the edge of the backplate 1300 to form a downward airstream along with the second purge gas flowing on the outside of the backplate 1300.

By such a downward airstream, the process gas supplied to the lower surface of the substrate S may be prevented from flowing to the upper surface of the substrate S.

The substrate processing apparatus according to the present invention has the technical advantages as follows.

According to the present invention having the configuration described above, it is possible to effectively exhaust the residual gas remaining in the processing space above the upper showerhead, the door opening of a chamber and the like by simultaneously performing the internal purge of the upper showerhead and the external purge of the upper showerhead.

In particular, according to the present invention, it is possible to establish a purge gas supply system with double flow paths that is not affected by the external environment during the substrate process.

Further, according to the present invention, it is possible to form the symmetrical flow paths of the purge gas directed downward from the edge of the upper showerhead, and further to provide the purge gas with a downward orientation so that the residual gas and the byproducts can be directed to the exhaust outlet and then be discharged.

Although a number of examples have been described, it should be understood that other modifications and implementations can be devised by those skilled in the art that will fall within the spirit and scope of the principles of the present invention. More particularly, various variations and modifications in the structure or the configuration are possible within the scope of the disclosure, the drawings, and the appended claims. In addition to variations and modifications in the configuration, alternative uses will also be apparent to those skilled in the art.

What is claimed is:

1. A substrate processing apparatus comprising:
a chamber configured to provide a processing space in which a process for a substrate is performed;
an upper showerhead plate provided in an upper region of an interior of the chamber and configured to supply purge gas;
a stem connected to an upper surface of the upper showerhead plate and configured to be internally supplied with the purge gas, the stem being formed with a first supply hole; and
a backplate configured to form a purge gas space between the backplate and the upper surface of the upper showerhead plate and formed with a second supply hole.

2. The substrate processing apparatus of claim 1, wherein the backplate is spaced apart from the stem on the upper surface of the upper showerhead plate.

3. The substrate processing apparatus of claim 2, wherein a gap between the stem and the backplate is from about 0.5 mm to about 5 mm on the upper surface of the upper showerhead plate.

4. The substrate processing apparatus of claim 1, wherein the purge gas supplied from the first supply hole flows into the purge gas space through the second supply hole.

5. The substrate processing apparatus of claim 1, wherein the first supply hole and the second supply hole are formed at substantially the same height from the upper surface of the upper showerhead plate.

6. The substrate processing apparatus of claim 1, wherein the backplate includes:
a body spaced apart from the upper surface of the upper showerhead plate and formed with an opening through which the stem passes; and
a first extension extending downwardly from an inner edge of the body and connected to the upper surface of the upper showerhead plate.

7. The substrate processing apparatus of claim 6, wherein the backplate further includes a second extension extending downwardly from an outer edge of the body and connected to the upper surface of the upper showerhead plate.

8. The substrate processing apparatus of claim 6, wherein the second supply hole is provided in the first extension.

9. The substrate processing apparatus of claim 1, wherein the upper showerhead plate and the backplate are made of aluminum material or ceramic material.
